(19) United States
(12) Patent Application Publication
(10) Pub. No.: US 2023/0200039 A1
(43) Pub. Date: Jun. 22, 2023

(54) INTEGRATED CIRCUIT AND STATIC RANDOM ACCESS MEMORY (SRAM)

(71) Applicant: SAMSUNG ELECTRONICS CO., LTD., Suwon-si (KR)

(72) Inventors: Hoonsung CHOI, Seoul (KR); Minuk LEE, Suwon-si (KR)

(73) Assignee: SAMSUNG ELECTRONICS CO., LTD., Suwon-si (KR)

(21) Appl. No.: 17/865,065

(22) Filed: Jul. 14, 2022

(30) Foreign Application Priority Data
Dec. 21, 2021 (KR) 10-2021-0184288

(51) Int. Cl. H01L 27/11; G11C 11/412

(52) U.S. Cl. CPC H01L 27/1104; G11C 11/412

(57) ABSTRACT

The present disclosure refers to integrated circuits and static random access memories. In an embodiment, an integrated circuit includes a first n-type metal oxide semiconductor (NMOS) region, a second NMOS region, a first p-type MOS (PMOS) region between the first NMOS region and the second NMOS region, a second PMOS region between the first PMOS region and the second NMOS region, and a first active bridge extending in a first direction and coupling the first NMOS region to the first PMOS region. A level of the first active bridge matches levels of the first electrode of the first pass transistor, the second electrode of the first pass transistor, the first electrode of the first pull-down transistor, the second electrode of the first pull-down transistor, the first electrode of the first pull-up transistor, and the second electrode of the first pull-up transistor.

### CROSS-REFERENCE TO RELATED APPLICATIONS

This application is based on and claims priority under 35 U.S.C. § 119 to Korean Patent Application No. 10-2021-0184288, filed on Dec. 21, 2021, in the Korean Intellectual Property Office, the disclosure of which is incorporated herein in its entirety by reference.

### BACKGROUND

The present disclosure relates to an integrated circuit and static random access memory (SRAM).

Because SRAM does not need to refresh data, the SRAM generally has a high operating speed and requires low operating power. Representative applications of SRAM may include memories for mobile devices, such as mobile phones. In general, an SRAM cell may include two pass transistors and two inverters forming a flip-flop circuit.

When SRAM cells are constructed using a complementary metal-oxide semiconductor (CMOS) process, it may be difficult to reduce the size of an SRAM cell because six transistors are arranged in a single SRAM cell. In particular, in a continuous scaling down process, margins between contacts and between metal interconnects for connecting a plurality of transistors and applying a signal may decrease, which may pose challenges to miniaturizing an SRAM cell.

### SUMMARY

The present disclosure provides for a semiconductor device having an increased degree of integration.

According to an aspect of the present disclosure, an integrated circuit is provided. The integrated circuit includes a first n-type metal oxide semiconductor (NMOS) region, a second NMOS region, a first p-type MOS (PMOS) region, a second PMOS region, and a first active bridge. The first NMOS region includes a first electrode of a first pass transistor, a second electrode of the first pass transistor, a first electrode of a first pull-down transistor, and a second electrode of the first pull-down transistor. The second NMOS region includes a first electrode of a second pass transistor, a second electrode of the second pass transistor, a first electrode of a second pull-down transistor, and a second electrode of the second pull-down transistor. The first PMOS region is between the first NMOS region and the second NMOS region. The first PMOS region includes a first electrode of a first pull-up transistor and a second electrode of the first pull-up transistor. The second PMOS region is between the first PMOS region and the second NMOS region. The second PMOS region includes a first electrode of a second pull-up transistor and a second electrode of the second pull-up transistor. The first active bridge extends in a first direction and couples the first NMOS region to the first PMOS region. Each of the first NMOS region, the second NMOS region, the first PMOS region, and the second PMOS region extends in a second direction perpendicular to the first direction. A first level of the first active bridge matches a level of the first electrode of the first pass transistor, a level of the second electrode of the first pass transistor, a level of the first electrode of the first pull-down transistor, a level of the second electrode of the first pull-down transistor, a level of the first electrode of the first pull-up transistor, and a level of the second electrode of the first pull-up transistor.

According to another aspect of the present disclosure, an integrated circuit is provided. The integrated circuit includes a substrate, a buried oxide layer, and an active layer. The substrate includes a first well region doped with a first p-type dopant and a second well region doped with a first n-type dopant. The buried oxide layer is on the substrate and includes an insulating material. The active layer is separated from the substrate by the buried oxide layer. The buried oxide layer is between the substrate and the active layer. The active layer includes a first electrode of a first pass transistor doped with a second n-type dopant, a second electrode of the first pass transistor doped with a third n-type dopant, a first electrode of a first pull-down transistor doped with a fourth n-type dopant, a second electrode of the first pull-down transistor doped with a fifth n-type dopant, a first electrode of a first pull-up transistor doped with a second p-type dopant, a second electrode of the first pull-up transistor doped with a third p-type dopant. The active bridge is configured to electrically couple the first electrode of the first pass transistor, the second electrode of the first pull-down transistor, and the first electrode of the first pull-up transistor.

According to another aspect of the present disclosure, a static random access memory (SRAM) is provided. The SRAM includes a first active pattern, a second active pattern, a first switching electrode, a second switching electrode, a third switching electrode, and a fourth switching electrode. The first active pattern has a letter H planar shape. The second active pattern has a letter H planar shape and is spaced apart from the first active pattern in a first direction. The first switching electrode vertically overlaps the first active pattern and extends in the first direction on the first active pattern. The second switching electrode vertically overlaps the first active pattern and the second active pattern. The second switching electrode is spaced apart from the first switching electrode in the first direction, and extends in the first direction on the first active pattern and the second active pattern. The third switching electrode vertically overlaps the first active pattern and the second active pattern. The third switching electrode is spaced apart from the first switching electrode in a second direction perpendicular to the first direction, and extends in the first direction on the first active pattern and the second active pattern. The fourth switching electrode vertically overlaps the second active pattern. The fourth switching electrode is spaced apart from the third switching electrode in the first direction, and extends in the first direction on the second active pattern.

According to another aspect of the present disclosure, an integrated circuit is provided. The integrated circuit includes a substrate, a buried oxide layer, an active layer, a silicide layer, and a first interlayer insulating layer. The substrate includes a first well region and a second well region. A first conductivity type of the first well region is opposite to a second conductivity type of the second well region. The buried oxide layer is on the substrate. The active layer is separated from the substrate by the buried oxide layer. The buried oxide layer is between the substrate and the active layer. The active layer includes a source electrode of a first pass transistor, a drain electrode of a first pull-down transistor, and a drain electrode of a first pull-up transistor. The silicide layer covers the source electrode of the first pass transistor, the drain electrode of the first pull-down transistor, and the drain electrode of the first pull-up transistor. The first interlayer insulating layer covers the active layer. The first interlayer insulating layer is in contact with an entire surface of a first portion of the silicide layer that is in contact with the source electrode of the first pass transistor. The interlayer insulating layer is in contact with an entire surface of a second portion of the silicide layer that is in contact with the drain electrode of the first pull-down transistor.

### BRIEF DESCRIPTION OF THE DRAWINGS

Embodiments of the present disclosure may be more clearly understood from the following detailed description taken in conjunction with the accompanying drawings in which:

FIG. 1 is an equivalent circuit diagram of an integrated circuit according to an example embodiment;

FIG. 2 illustrates a layout of an integrated circuit according to example embodiments;

FIG. 3A is a cross-sectional view taken along a line 2I-2I′ of FIG. 2;

FIG. 3B is a cross-sectional view taken along a line 2II-2II′ of FIG. 2;

FIG. 3C is a cross-sectional view taken along a line 2III-2III′ of FIG. 2;

FIG. 3D is an enlarged view of regions in the vicinity of a first active bridge of FIG. 2;

FIG. 3E selectively illustrates only a configuration of a portion of the integrated circuit of FIG. 2;

FIG. 4 is a cross-sectional view for explaining an integrated circuit according to other example embodiments;

FIG. 5 is a cross-sectional view for explaining an integrated circuit according to other example embodiments;

FIG. 6A illustrates a layout of an integrated circuit according to other example embodiments;

FIG. 6B illustrates a layout of an integrated circuit according to other example embodiments;

FIG. 6C illustrates a layout of an integrated circuit according to other example embodiments;

FIG. 7A illustrates a layout of an integrated circuit according to other example embodiments;

FIG. 7B is a cross-sectional view taken along a line 7I-7I′ of FIG. 7A;

FIG. 8A illustrates a layout of an integrated circuit according to other example embodiments;

FIG. 8B illustrates a layout of an integrated circuit according to other example embodiments;

FIG. 8C illustrates a layout of an integrated circuit according to other example embodiments; and

FIG. 8D illustrates a layout of an integrated circuit according to other example embodiments.

### DETAILED DESCRIPTION

The embodiments described herein are example embodiments, and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments of the present disclosure are described in detail with reference to the accompanying drawings. Like reference numerals denote like elements in the figures, and repeated descriptions thereof will be omitted herein.

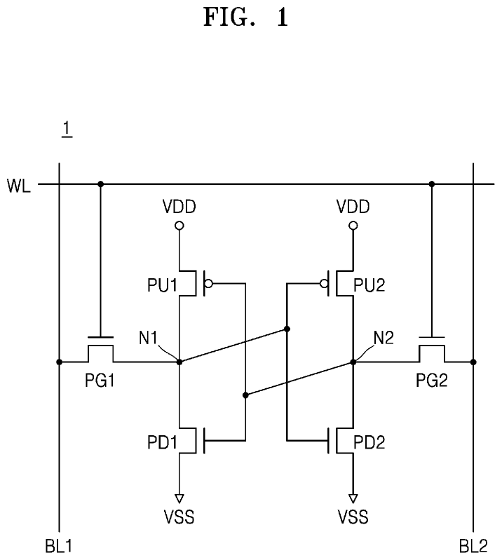

FIG. 1 is an equivalent circuit diagram of an integrated circuit 1 according to an example embodiment.

Referring to FIG. 1, the integrated circuit 1 may include first and second bit lines BL1 and BL2, a word line WL, and a plurality of transistors. For example, the integrated circuit 1 may include a first pass transistor PG1, a second pass transistor PG2, a first pull-up transistor PU1, a second pull-up transistor PU2, a first pull-down transistor PD1, and a second pull-down transistor PD2.

Each of the first pull-up transistor PU1 and the second pull-up transistor PU2 may be P-type metal-oxide-semiconductor field effect transistors (MOSFETs). Each of the first pass transistor PG1, the second pass transistor PG2, the first pull-down transistor PD1, and the second pull-down transistor PD2 may be N-type MOSFETs. In some embodiments, the integrated circuit 1 may include six transistors consisting of four n-type MOS (NMOS) transistors (e.g., PG1, PG2, PD1, and PD2) and two p-type MOS (PMOS) transistors (e.g., PG1 and PG2).

Switching electrodes (e.g., gate electrodes) of the first and second pass transistors PG1 and PG2 may be connected to the word line WL. A second electrode (e.g., a drain electrode) of the first pass transistor PG1 may be connected to the first bit line BL1, and a second electrode (e.g., a drain electrode) of the second pass transistor PG2 may be connected to the second bit line BL2. Positive supply voltages VDD may be applied to first electrodes (or source electrodes) of the first and second pull-up transistors PU1 and PU2. Negative supply voltages VSS may be applied to first electrodes (e.g., source electrodes) of the first and second pull-down transistors PD1 and PD2.

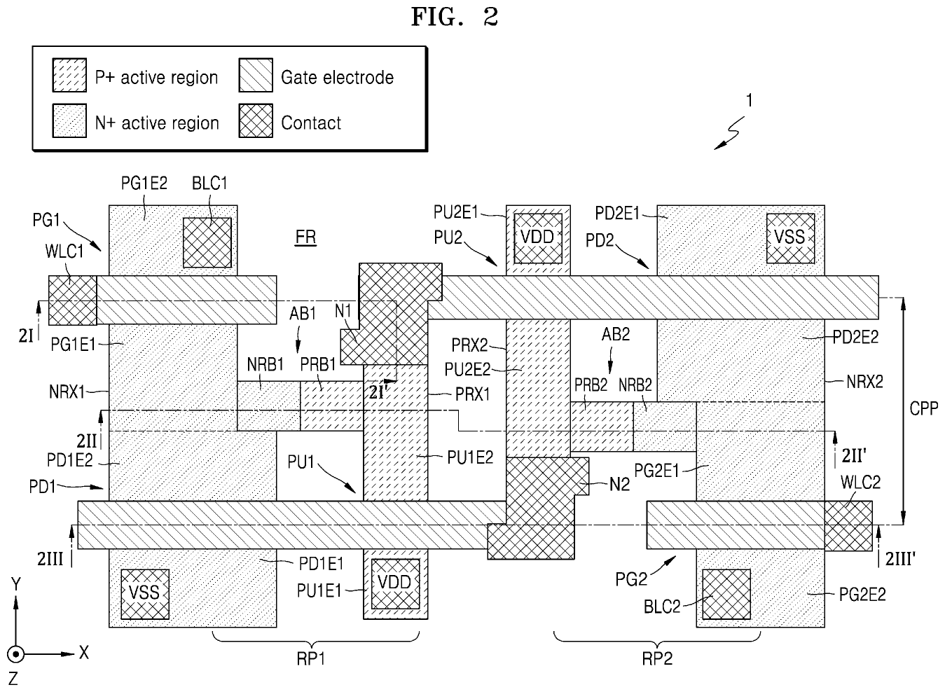

A first electrode (e.g., a source electrode) of the first pass transistor PG1, a second electrode (e.g., a drain electrode) of the first pull-up transistor PU1, and a second electrode (e.g., a drain electrode) of the first pull-down transistor PD1 may be commonly coupled to a first node N1. According to example embodiments, the first electrode (e.g., the source electrode) of the first pass transistor PG1 and the second electrode (e.g., the drain electrode) of the first pull-down transistor PD1 may be configured to be electrically connected (e.g., electrically coupled) to the second electrode (e.g., the drain electrode) of the first pull-up transistor PU1 via a first active bridge (e.g., AB1 of FIG. 2).

According to example embodiments, a first electrode (e.g., a source electrode) of the second pass transistor PG2, a second electrode (e.g., a drain electrode) of the second pull-up transistor PU2, and a second electrode (e.g., a drain electrode) of the second pull-down transistor PD2 may be commonly connected to a second node N2. According to example embodiments, the first electrode (e.g., the source electrode) of the second pass transistor PG2 and the second electrode (e.g., the drain electrode) of the second pull-down transistor PD2 may be configured to be electrically connected to the second electrode (e.g., the drain electrode) of the second pull-up transistor PU2 via a second active bridge (e.g., AB2 of FIG. 2).

A switching electrode (e.g., a gate electrode) of the first pull-up transistor PU1 and a switching electrode (e.g., a gate electrode) of the first pull-down transistor PD1 may be commonly connected to the second node N2. A switching electrode (e.g., a gate electrodes) of the second pull-up transistor PU2 and a switching electrode (e.g., a gate electrode) of the second pull-down transistor PD2 may be commonly connected to the first node N1. Alternatively or additionally, the first and second pull-up transistors PU1 and PU2 and the first and second pull-down transistors PD1 and PD2 may constitute a latch circuit including a pair of complementary metal-oxide-semiconductor (CMOS) inverters.

When a high signal is applied to the first node N1, the second pull-up transistor PU2 is turned off and the second pull-down transistor PD2 is turned on, so that a low signal is applied to the second node N2. As the low signal is applied to the second node N2, the first pull-up transistor PU1 is turned on and the first pull-down transistor PD1 is turned off, so that the first node N1 maintains a high signal.

When a high signal is applied to the second node N2, the first pull-up transistor PU1 is turned off and the first pull-down transistor PD1 is turned on, so that a low signal is applied to the first node N1. As the low signal is applied to the first node N1, the second pull-up transistor PU2 is turned on and the second pull-down transistor PD2 is turned off, so that the second node N2 maintains a high signal.

Therefore, when the first and second pass transistors PG1 and PG2 are turned on in response to a switching signal applied to the word line WL, data signals provided to the first and second bit lines BL1 and BL2 may be respectively latched at the first and second nodes N1 and N2 via the first and second pass transistors PG1 and PG2. When the first and second pass transistors PG1 and PG2 are turned on, data latched at the first and second nodes N1 and N2 may be respectively provided to the first and second bit lines BL1 and BL2 via the first and second pass transistors PG1 and PG2. Data latched at the first and second nodes N1 and N2 may be read by sensing signals provided to the first and second bit lines BL1 and BL2 through a sense amplifier (not shown).

FIG. 2 illustrates a layout of an integrated circuit 1 according to example embodiments.

Referring to FIG. 2, the integrated circuit 1 may be designed to perform a predefined function as a cell that is a basic unit in a layout for forming a semiconductor device, and may also be referred to as a standard cell. A semiconductor device such as static random access memory (SRAM) may include multiple cells having various functions, including the integrated circuit 1, and the multiple cells may be arranged in a plurality of rows and columns.

Hereinafter, a plane consisting of an X-axis and a Y-axis may be referred to as a horizontal plane, a component arranged in the +Z direction relative to another component may be referred to as being above the other component, and a component arranged in a −Z direction relative to another component may be referred to as being below the other component. In addition, an area of a component may refer to a space occupied by the component on a plane parallel to the horizontal plane, and a height of the component may refer to a length of the component in a Y-axis direction.

The integrated circuit 1 may include first and second NMOS regions NRX1 and NRX2 in which N-type MOSFETs are arranged and first and second PMOS regions PRX1 and PRX2 in which P-type MOSFETs are arranged. Each of the first and second NMOS regions NRX1 and NRX2 and the first and second PMOS regions PRX1 and PRX2 may extend in the Y direction. The first and second NMOS regions NRX1 and NRX2 may be spaced apart from each other in the X direction with the first and second PMOS regions PRX1 and PRX2 therebetween. The second PMOS region PRX2 may be spaced apart from the first NMOS region NRX1 in the X direction with the first PMOS region PRX1 therebetween.

According to example embodiments, the first NMOS region NRX1 may include first and second electrodes PG1E1 and PG1E2 of a first pass transistor PG1 and first and second electrodes PD1E1 and PD1E2 of a first pull-down transistor PD1. The first and second electrodes PG1E1 and PG1E2 of the first pass transistor PG1 and the first and second electrodes PD1E1 and PD1E2 of the first pull-down transistor PD1 may be sequentially arranged in the Y direction.

According to example embodiments, the second NMOS region NRX2 may include first and second electrodes PG2E1 and PG2E2 of a second pass transistor PG2 and first and second electrodes PD2E1 and PD2E2 of a second pull-down transistor PD2. The first and second electrodes PG2E1 and PG2E2 of the second pass transistor PG2 and the first and second electrodes PD2E1 and PD2E2 of the second pull-down transistor PD2 may be sequentially arranged in the Y direction.

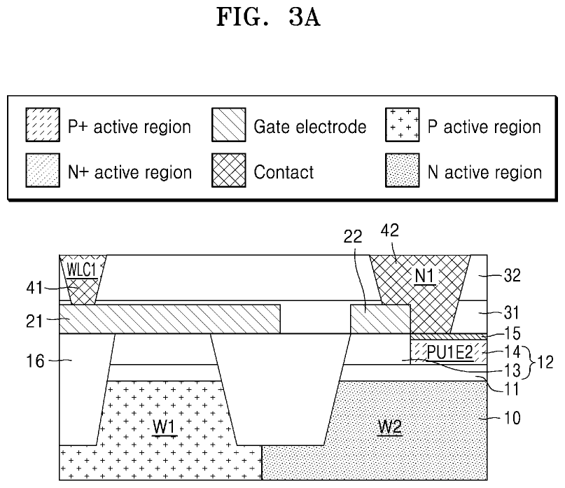

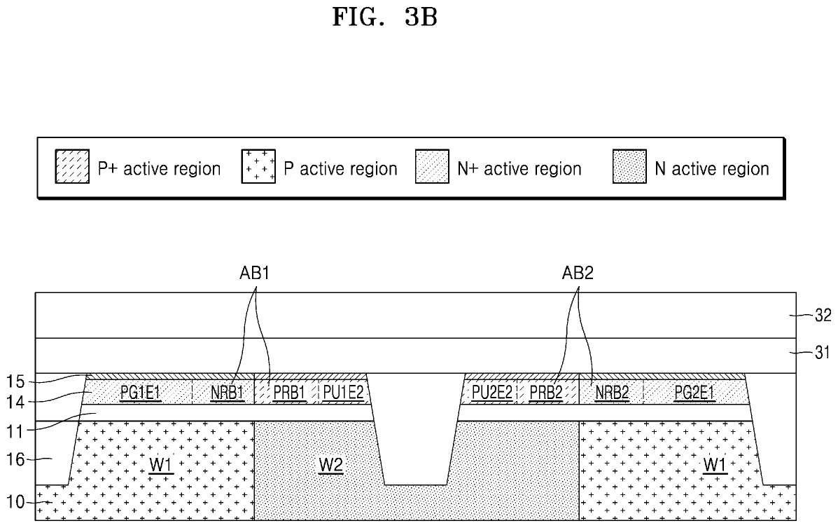

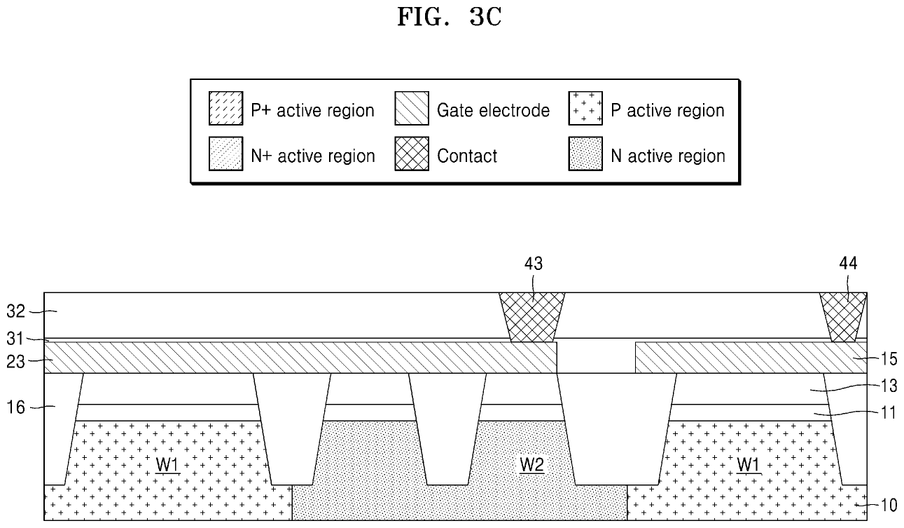

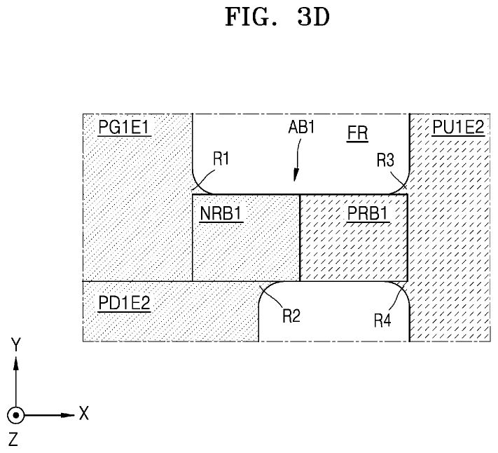

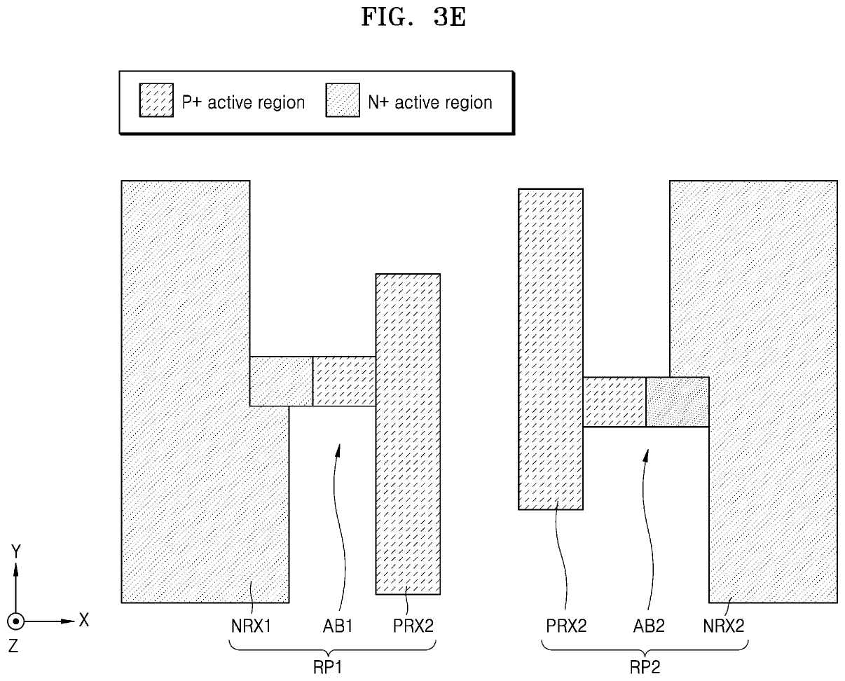

The first and second NMOS regions NRX1 and NRX2 and the first and second PMOS regions PRX1 and PRX2 may be horizontally surrounded by a field region FR. The field region FR is a region where a device isolation layer (e.g., device isolation layer 16 of FIG. 3A) is arranged. That is, the first and second NMOS regions NRX1 and NRX2 and the first and second PMOS regions PRX1 and PRX2 may be portions not covered by the device isolation layer 16.

According to example embodiments, the integrated circuit 1 may be repeatedly arranged on a plane to provide a semiconductor device having a memory of a set size. For example, the first and second NMOS regions NRX1 and NRX2 may be respectively continuous active regions integrated with first and second NMOS regions NRX1 and NRX2 in a neighboring cell, and the first and second PMOS regions PRX1 and PRX2 may be respectively discontinuous active regions separated from first and second NMOS regions NRX1 and NRX2 in a neighboring cell. According to example embodiments, each of the first and second NMOS regions NRX1 and NRX2 may have a length in the Y direction greater than a length in the Y direction of each of the first and second PMOS regions PRX1 and PRX2.

The first and second NMOS regions NRX1 and NRX2 may each have a variable width in the X direction. For example, a first portion of the first NMOS region NRX1 may have a width in the X direction less than a width of a second portion in the X direction. That is, each of the first and second electrodes PG1E1 and PG1E2 of the first pass transistor PG1 may have a width less than that of each of the first and second electrodes PD1E1 and PD1E2 of the first pull-down transistor PD1. Similarly, each of the first and second electrodes PG2E1 and PG2E2 of the second pass transistor PG2 may have a width less than that of each of the first and second electrodes PD2E1 and PD2E2 of the second pull-down transistor PD2. The first and second PMOS regions PRX1 and PRX2 may have a substantially constant width in the X direction.

FIG. 3A is a cross-sectional view taken along line 2I-2I′ of FIG. 2. FIG. 3B is a cross-sectional view taken along a line 2II-2II′ of FIG. 2. FIG. 3C is a cross-sectional view taken along a line 2III-2III′ of FIG. 2. FIG. 3D is an enlarged view of regions in the vicinity of the first active bridge AB1 of FIG. 2. FIG. 3E illustrates the first NMOS region NRX1, the first active bridge AB1, the first PMOS region PRX1, the second NMOS region NRX2, the second active bridge AB2, and the second PMOS region PRX2.

Referring to FIGS. 2 and 3A, the integrated circuit 1 may include a fully depleted silicon-on-insulator (FDSOI) structure. The integrated circuit 1 may include a substrate 10, a buried oxide layer 11 disposed on the substrate 10, and an active layer 12 disposed on the buried oxide layer 11.

According to example embodiments, the substrate 10 may be a bulk silicon (Si) substrate. As a non-limiting example, the substrate 10 may include silicon germanium (SiGe), indium antimonide (InSb), a lead telluride (PbTe) compound, indium arsenide (InAs), phosphide, gallium arsenide (GaAs), or gallium antimonide (GaSb).

The substrate 10 may include first and second well regions W1 and W2. The first and second well regions W1 and W2 may be positioned in an upper portion of the substrate 10. A lower portion (not shown) of the substrate 10 may be apart from a top surface of the substrate 10, so that impurities for forming the first and second well regions W1 and W2 may not be implanted.

According to example embodiments, the first and second well regions W1 and W2 may have different conductivity types. In example embodiments, the first well region W1 may be doped with p-type dopant, and the second well region W2 may be doped with an N-type dopant. N-type MOSFETs may be arranged in the first well region W1, and P-type MOSFETs may be arranged in the second well region W2. However, embodiments are not limited thereto, and each of the first and second well regions W1 and W2 may be doped with p-type dopant.

The buried oxide layer 11 may cover the top surface of the substrate 10. The buried oxide layer 11 may include, for example, silicon oxide. According to example embodiments, the buried oxide layer 11 overlying the substrate 10 may be provided using a silicon on sapphire (SOS) process for growing a hetero-epitaxial silicon layer on a sapphire substrate, a separation-by-implanted-oxygen (SIMOX) process for forming a buried silicon oxide layer by implanting oxygen ions into a Si substrate and then annealing the resulting substrate, a bonding silicon-on-insulator (SOI) process for bonding at least one wafer having an insulating layer on a surface thereof to another wafer, etc.

The active layer 12 may include channel regions 13 and source/drain regions 14. The channel regions 13 may be overlapped by first and second switching electrodes 21 and 22 (e.g., gate electrodes) vertically (e.g., in a Z direction). The source/drain regions 14 may be arranged adjacent to the channel regions 13. The source/drain regions 14 may be spaced apart from each other with the channel region 13 therebetween. That is, the channel region 13 may be between the source/drain regions 14. The source/drain regions 14 may not be vertically overlapped by the first and second gate electrodes 21 and 22.

The channel regions 13 may include, for example, a semiconductor material. In example embodiments, the channel regions 13 may include a Si layer or a SiGe layer provided using an epitaxial growth process or the like. According to example embodiments, the channel regions 13 may be doped to have a conductivity type different from that of the source/drain regions 14 adjacent thereto. For example, the channel regions 13 adjacent to the source/drain regions 14 of an N type may be doped with P-type dopants, and the channel regions 13 adjacent to the source/drain regions 14 of a P type may be doped with N-type dopants.

The source/drain regions 14 may include the first and second electrodes PG1E1 and PG1E2 of the first pass transistor PG1 and the first and second electrodes PG2E1 and PG2E2 of the second pass transistor PG2, the first and second electrodes PU1E1 and PU1E2 of the first pull-up transistor PU1, the first and second electrodes PU2E1 and PU2E2 of the second pull-up transistor PU2, the first and second electrodes PD1E1 and PD1E2 of the first pull-down transistor PD1, and the first and second electrodes PD2E1 and PD2E2 of the second pull-down transistor PD2.

Some of the source/drain regions 14 may be doped with P-type dopants, and the other source/drain regions 14 may be doped with N-type dopants. For example, the first and second electrodes PG1E1 and PG1E2 of the first pass transistor PG1, the first and second electrodes PG2E1 and PG2E2 of the second pass transistor PG2, the first and second electrodes PD1E1 and PD1E2 of the first pull-down transistor PD1, and the first and second electrodes PD2E1 and PD2E2 of the second pull-down transistor PD2 may be doped with N-type dopants, whereas the first and second electrodes PU1E1 and PU1E2 of the first pull-up transistor PU1 and the first and second electrodes PU2E1 and PU2E2 of the second pull-up transistor PU2 may be doped with P-type dopants.

The channel region 13 between the first and second electrodes PG1E1 and PG1E2 of the first pass transistor PG1, the channel region 13 between the first and second electrodes PG2E1 and PG2E2 of the second pass transistor PG2, the channel region 13 between the first and second electrodes PD1E1 and PD1E2 of the first pull-down transistor PD1, and the channel region 13 between the first and second electrodes PD2E1 and PD2E2 of the second pull-down transistor PD2 may be doped with P-type dopants. The channel region 13 between the first and second electrodes PU1E1 and PU1E2 of the first pull-up transistor PU1 and the channel region 13 between the first and second electrodes PU2E1 and PU2E2 of the second pull-up transistor PU2 may be doped with N-type dopants.

A silicide layer 15 may be disposed on the source/drain regions 14. The silicide layer 15 may be formed by providing a conformal metal material layer on the source/drain regions 14 and then annealing the metal material layer. In example embodiments, the silicide layer 15 may include a compound containing a metal material, such as nickel (Ni), cobalt (Co), platinum (Pt), titanium (Ti), etc., and a semiconductor material, such as Si. Due to the formation of the silicide layer 15, a contact resistance between the source/drain regions 14 (e.g., the second electrode PU1E2) and a source/drain contact (e.g., a first tie-down contact 42) may be reduced.

In example embodiments, the device isolation layer 16 may be a shallow trench isolation (STI) layer. The device isolation layer 16 may include, for example, an insulating material, such as silicon oxide. The device isolation layer 16 may be between the first NMOS region NRX1 and the first PMOS region PRX1. The first NMOS region NRX1 and the first PMOS region PRX1 may be spaced apart from each other horizontally (e.g., in the X direction) with the device isolation layer 16 therebetween. That is, the device isolation layer 16 may be between the first NMOS region NRX1 and the first PMOS region PRX1.

The first and second switching electrodes 21 and 22 may each extend across the channel regions 13 in the X direction. The first and second switching electrodes 21 and 22 may each further include a portion overlying the device isolation layer 16. In example embodiments, the first and second switching electrodes 21 and 22 may be disposed on the channel regions 13 of the active layer 12 and the device isolation layer 16. The first and second switching electrodes 21 and 22 may be spaced apart from each other in the X direction.

The first switching electrode 21 may be a switching electrode (e.g., a gate electrode) of the first pass transistor PG1. The second switching electrode 22 may include a switching electrode (e.g., a gate electrode) of the second pull-up transistor PU2 and a switching electrode (e.g., a gate electrode) of the second pull-down transistor PD2. Alternatively or additionally, a gate dielectric layer (not shown) may be further between the first and second switching electrodes 21 and 22 and the channel regions 13, gate spacers may be further provided on sides of the first and second switching electrodes 21 and 22 to cover the sides thereof, and a gate silicide layer may be further provided to cover top surfaces of the first and second switching electrodes 21 and 22.

According to example embodiments, the gate dielectric layer may include a high dielectric constant (high-k) material. The gate dielectric layer may have a higher dielectric constant than that of silicon nitride. For example, the dielectric constant of the gate dielectric layer may be greater than or equal to 10. In example embodiments, the gate dielectric layer may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but is not limited thereto.

In example embodiments, a gate conductive layer may include a metal material. For example, the gate conductive layer may include Ti, tantalum (Ta), tungsten (W), aluminum (Al), Co, or a combination thereof As another example, the gate conductive layer may include a semiconductor material, such as Si or SiGe. As another example, the gate conductive layer may include a multilayer structure in which two or more conductive materials are stacked. For example, the gate conductive layer may include a conformal deposition structure of a work function adjustment layer including one of titanium oxide (TiN), tantalum nitride (TaN), titanium carbide (TiC), tantalum carbide (TaC), titanium aluminum carbide (TiAlC), and a combination thereof, and a conductive filling layer including W or Al to fill the inside of the conformal deposition structure.

In example embodiments, the gate spacers may include an insulating material. The gate spacers may include, for example, silicon nitride, such as Si₃N₄. The gate spacers may cover sidewalls of the gate conductive layer. Accordingly, the gate spacers may prevent unwanted electrical shorts and/or diffusion of materials from the gate conductive layer.

The gate silicide layer may include a metal silicide material. The gate silicide layer may be formed simultaneously with the silicide layer 15. The gate silicide layer may reduce a contact resistance between the first switching electrode 21 and a first switching contact 41.

First and second interlayer insulating layers 31 and 32 may be disposed over the channel regions 13, the source/drain regions 14, the device isolation layer 16, and the first and second switching electrodes 21 and 22. The first and second interlayer insulating layers 31 and 32 may each include a low-k material. The first and second interlayer insulating layers 31 and 32 may each include, for example, silicon oxide. The first and second interlayer insulating layers 31 and 32 may each include plasma enhanced oxide (PEOX), tetraethyl orthosilicate (TEOS), boro TEOS (BTEOS), phosphorous TEOS (PTEOS), boro-phospho TEOS (BPTEOS), borosilicate glass (BSG), phosphosilicate glass (PSG), borophosphosilicate glass (BPSG), or the like.

The first interlayer insulating layer 31 may cover the first and second switching electrodes 21 and 22. The second interlayer insulating layer 32 may cover side surfaces of the first switching contact 41 and a second switching contact (e.g., second switching contact 44 of FIG. 3C). The second interlayer insulating layer 32 may cover side surfaces of the first tie-down contact 42 and a second tie-down contact (e.g., second tie-down contact 43 of FIG. 3C).

The first switching contact 41 and the first tie-down contact 42 may each extend in a direction (e.g., the Z direction) perpendicular to the substrate 10. The first switching contact 41 and the first tie-down contact 42 may each include, but are not limited to, conductive materials, such as Al and copper (Cu). Alternatively or additionally, passivation layers including TiN (not shown) may be further provided between the first interlayer insulating layer 31 and the first switching contact 41 and between the second interlayer insulating layer 32 and the first switching contact 41 and between the first interlayer insulating layer 31 and the first tie-down contact 42 and between the second interlayer insulating layer 32 and the first tie-down contact 42.

The first switching contact 41 may be configured to be electrically connected to the first switching electrode 21. The first switching contact 41 may be in contact with the first switching electrode 21. The first switching contact 41 may be a first word line contact WLC1 for connecting the word line (WL of FIG. 1) to the first switching electrode 21.

According to example embodiments, the first tie-down contact 42 may have a bar shape extending in a horizontal direction (e.g., a Y direction). According to example embodiments, the first tie-down contact 42 may extend in a direction (e.g., the Y direction) perpendicular to the direction (e.g., the X direction) in which the second switching electrode 22 extends.

In example embodiments, the first tie-down contact 42 may be configured to be electrically connected (e.g., coupled) to the second electrode PU1E2 of the first pull-up transistor PU1 and the second switching electrode 22. In example embodiments, the first tie-down contact 42 may contact each of the second electrode PU1E2 of the first pull-up transistor PU1 and the second switching electrode 22. In example embodiments, the second electrode PU1E2 of the first pull-up transistor PU1 and the second switching electrode 22 may be short-circuited to each other by the first tie-down contact 42. According to example embodiments, the first tie-down contact 42 may be the first node N1 of FIG. 1. According to example embodiments, the gate electrodes of the second pull-up and pull-down transistors PU2 and PD2 may be connected to the second electrode PU1E2 of the first pull-up transistor PU1 via the first tie-down contact 42.

Referring to FIGS. 2 and 3B, the active layer 12 may further include the first active bridge AB1 including a first N-type active bridge NRB1 and a first P-type active bridge PRB1 and the second active bridge AB2 including a second N-type active bridge NRB2 and a second P-type active bridge PRB2.

Accordingly, the first and second active bridges AB1 and AB2 may be at the same level from the substrate 10 as the first and second electrodes PG1E1 and PG1E2 of the first pass transistor PG1, the first and second electrodes PG2E1 and PG2E2 of the second pass transistor PG2, the first and second electrodes PD1E1 and PD1E2 of the first pull-down transistor PD1, the first and second electrodes PD2E1 and PD2E2 of the second pull-down transistor PD2, the first and second electrodes PU1E1 and PU1E2 of the first pull-up transistor PU1, and the first and second electrodes PU2E1 and PU2E2 of the second pull-up transistor PU2.

In example embodiments, top surfaces of the first and second active bridges AB1 and AB2 may be coplanar with top surfaces of the first and second electrodes PG1E1 and PG1E2 of the first pass transistor PG1, top surfaces of the first and second electrodes PG2E1 and PG2E2 of the second pass transistor PG2, top surfaces of the first and second electrodes PD1E1 and PD1E2 of the first pull-down transistor PD1, top surfaces of the first and second electrodes PD2E1 and PD2E2 of the second pull-down transistor PD2, top surfaces of the first and second electrodes PU1E1 and PU1E2 of the first pull-up transistor PU1, and top surfaces of the first and second electrodes PU2E1 and PU2E2 of the second pull-up transistor PU2.

According to example embodiments, bottom surfaces of the first and second active bridges AB1 and AB2 may be coplanar with bottom surfaces of the first and second electrodes PG1E1 and PG1E2 of the first pass transistor PG1, bottom surfaces of the first and second electrodes PG2E1 and PG2E2 of the second pass transistor PG2, bottom surfaces of the first and second electrodes PD1E1 and PD1E2 of the first pull-down transistor PD1, bottom surfaces of the first and second electrodes PD2E1 and PD2E2 of the second pull-down transistor PD2, bottom surfaces of the first and second electrodes PU1E1 and PU1E2 of the first pull-up transistor PU1, and bottom surfaces of the first and second electrodes PU2E1 and PU2E2 of the second pull-up transistor PU2.

In example embodiments, the first N-type active bridge NRB1, the first P-type active bridge PRB1, the second N-type active bridge NRB2, and the second P-type active bridge PRB2 may be at the same level from the substrate 10 as the channel regions (e.g., channel regions 13 of FIG. 3A) and the source/drain regions (e.g., source/drain regions 14 of FIG. 3A).

In example embodiments, the first active bridge AB1 may be between the first NMOS and PMOS regions NRX1 and PRX1. In example embodiments, the second active bridge AB2 may be between the second NMOS and PMOS regions NRX2 and PRX2.

According to example embodiments, the first active bridge AB1 may extend in a direction (e.g., the X direction) perpendicular to a direction (e.g., the Y direction) in which the first NMOS and PMOS regions NRX1 and PRX1 extend. According to example embodiments, the second active bridge AB2 may extend in a direction (e.g., the X direction) perpendicular to a direction (e.g., the Y direction) in which the second NMOS and PMOS regions NRX2 and PRX2 extend.

In example embodiments, the first active bridge AB1 may connect the first NMOS region NRX1 to the first PMOS region PRX1. In example embodiments, the second active bridge AB2 may connect the second NMOS region NRX2 to the second PMOS region PRX2.

The first N-type active bridge NRB1 may connect the first electrode PG1E1 of the first pass transistor PG1 to the second electrode PD1E2 of the first pull-down transistor PD1. The first N-type active bridge NRB1 may be connected to the first P-type active bridge PRB1. The first P-type active bridge PRB1 may be connected to the second electrode PU1E2 of the first pull-up transistor PU1.

The first N-type active bridge NRB1 may be doped at substantially the same concentration as the first electrode PG1E1 of the first pass transistor PG1 and the second electrode PD1E2 of the first pull-down transistor PD1. The first P-type active bridge PRB1 may be doped at substantially the same concentration as the second electrode PU1E2 of the first pull-up transistor PU1.

According to example embodiments, a contact may not be provided on the first electrode PG1E1 of the first pass transistor PG1, the second electrode PD1E2 of the first pull-down transistor PD1, the first N-type active bridge NRB1, and the first P-type active bridge PRB1.

In example embodiments, an entire top surface of the first electrode PG1E1 of the first pass transistor PG1 may be overlapped by the first interlayer insulating layer 31 in the vertical (Z) direction. In optional or additional embodiments, the first interlayer insulating layer 31 may overlap in the vertical (Z) direction at least a portion of the top surface of the first electrode PG1E1 of the first pass transistor PG1. In example embodiments, an entire top surface of the second electrode PD1E2 of the first pull-down transistor PD1 may be overlapped by the first interlayer insulating layer 31 in the vertical (Z) direction. In optional or additional embodiments, the first interlayer insulating layer 31 may overlap in the vertical (Z) direction at least a portion of the top surface of the second electrode PD1E2 of the first pull-down transistor PD1. In example embodiments, an entire top surface of the first N-type active bridge NRB1 may be overlapped by the first interlayer insulating layer 31 in the vertical (Z) direction. In optional or additional embodiments, the first interlayer insulating layer 31 may overlap in the vertical (Z) direction at least a portion of the top surface of the first N-type active bridge NRB1. In example embodiments, an entire top surface of the first P-type active bridge PRB1 may be overlapped by the first interlayer insulating layer 31 in the vertical (Z) direction. In optional or additional embodiments, the first interlayer insulating layer 31 may overlap in the vertical (Z) direction at least a portion of the top surface of the first P-type active bridge PRB1.

In example embodiments, a portion of the silicide layer 15 overlapping the entire top surface of the first electrode PG1E1 of the first pass transistor PG1 may contact the first interlayer insulating layer 31. In optional or additional embodiments, the portion of the silicide layer 15 in contact with the first interlayer insulating layer 31 may overlap at least a portion of the top surface of the first electrode PG1E1 of the first pass transistor PG1. A portion of the silicide layer 15 overlapping the entire top surface of the second electrode PD1E2 of the first pull-down transistor PD1 may be in contact with the first interlayer insulating layer 31. In optional or additional embodiments, the portion of the silicide layer 15 in contact with the first interlayer insulating layer 31 may overlap at least a portion of the top surface of the second electrode PD of the first pull-down transistor PD1. A portion of the silicide layer 15 overlapping the entire top surface of the first N-type active bridge NRB1 may be in contact with the first interlayer insulating layer 31. In optional or additional embodiments, the portion of the silicide layer 15 in contact with the first interlayer insulating layer 31 may overlap at least a portion of the top surface of the first N-type active bridge NRB1. A portion of the silicide layer 15 overlapping the entire top surface of the first P-type active bridge PRB1 may be in contact with the first interlayer insulating layer 31. In optional or additional embodiments, the portion of the silicide layer 15 in contact with the first interlayer insulating layer 31 may overlap at least a portion of the top surface of the first P-type active bridge PRB1.

In example embodiments, the first electrode PG1E1 of the first pass transistor PG1 and the second electrode PD1E2 of the first pull-down transistor PD1 may be connected to the second electrode PU1E2 of the first pull-up transistor PU1 by the first active bridge AB1. This may eliminate the need of forming a contact connecting the first electrode PG1E1 of the first pass transistor PG1 and the second electrode PD1E2 of the first pull-down transistor PD1 to the second electrode PU1E2 of the first pull-up transistor PU1 and accordingly, the degrees of freedom in a subsequent design of an interconnect layer may be enhanced.

The second N-type active bridge NRB2 may connect the first electrode PG2E1 of the second pass transistor PG2 to the second electrode PD2E2 of the second pull-down transistor PD2. The second N-type active bridge NRB2 may be connected to the second P-type active bridge PRB2. The second P-type active bridge PRB2 may be connected to the second electrode PU2E2 of the second pull-up transistor PU2.

The second N-type active bridge NRB2 may be doped at substantially the same concentration as the first electrode PG2E1 of the second pass transistor PG2 and the second electrode PD2E2 of the second pull-down transistor PD2. The second P-type active bridge PRB2 may be doped at substantially the same concentration as the second electrode PU2E2 of the second pull-up transistor PU2.

According to example embodiments, contacts may not be provided on the first electrode PG2E1 of the second pass transistor PG2, the second electrode PD2E2 of the second pull-down transistor PD2, the second N-type active bridge NRB2, and the second P-type active bridge PRB2.

In example embodiments, an entire top surface of the first electrode PG2E1 of the second pass transistor PG2 may be overlapped by the first interlayer insulating layer 31 in the vertical (Z) direction. In optional or additional embodiments, the first interlayer insulating layer 31 may overlap in the vertical (Z) direction at least a portion of the top surface of the first electrode PG2E1 of the second pass transistor PG2. In example embodiments, an entire top surface of the second electrode PD2E2 of the second pull-down transistor PD2 may be overlapped by the first interlayer insulating layer 31 in the vertical (Z) direction. In optional or additional embodiments, the first interlayer insulating layer 31 may overlap in the vertical (Z) direction at least a portion of the top surface of the second electrode PD2E2 of the second pull-down transistor PD2. In example embodiments, an entire top surface of the second N-type active bridge NRB2 may be overlapped by the first interlayer insulating layer 31 in the vertical (Z) direction. In optional or additional embodiments, the first interlayer insulating layer 31 may overlap in the vertical (Z) direction at least a portion of the top surface of the second N-type active bridge NRB2. In example embodiments, an entire top surface of the second P-type active bridge PRB2 may be overlapped by the first interlayer insulating layer 31 in the vertical (Z) direction. In optional or additional embodiments, the first interlayer insulating layer 31 may overlap in the vertical (Z) direction at least a portion of the top surface of the second P-type active bridge PRB2.

In example embodiments, a portion of the silicide layer 15 overlapping the entire top surface of the first electrode PG2E1 of the second pass transistor PG2 may be in contact with the first interlayer insulating layer 31. In optional or additional embodiments, the portion of the silicide layer 15 in contact with the first interlayer insulating layer 31 may overlap at least a portion of the top surface of the first electrode PG2E1 of the second pass transistor PG2. A portion of the silicide layer 15 overlapping the entire top surface of the second electrode PD2E2 of the second pull-down transistor PD2 may be in contact with the first interlayer insulating layer 31. In optional or additional embodiments, the portion of the silicide layer 15 in contact with the first interlayer insulating layer 31 may overlap at least a portion of the top surface of the second electrode PD2E2 of the second pull-down transistor PD2. A portion of the silicide layer 15 overlapping the entire top surface of the second N-type active bridge NRB2 may be in contact with the first interlayer insulating layer 31. In optional or additional embodiments, the portion of the silicide layer 15 in contact with the first interlayer insulating layer 31 may overlap at least a portion of the top surface of the second N-type active bridge NRB2. A portion of the silicide layer 15 overlapping the entire top surface of the second P-type active bridge PRB2 may be in contact with the first interlayer insulating layer 31. In optional or additional embodiments, the portion of the silicide layer 15 in contact with the first interlayer insulating layer 31 may overlap at least a portion of the top surface of the second P-type active bridge PRB2.

In example embodiments, the first electrode PG2E1 of the second pass transistor PG2 and the second electrode PD2E2 of the second pull-down transistor PD2 may be connected to the second electrode PU2E2 of the second pull-up transistor PU2 by the second active bridge AB2. Such a configuration may eliminate the need of forming a contact connecting the first electrode PG2E1 of the second pass transistor PG2 and the second electrode PD2E2 of the second pull-down transistor PD2 to the second electrode PU2E2 of the second pull-up transistor PU2 and accordingly, the degrees of freedom in a subsequent design of an interconnect layer may be enhanced.

The first and second N-type active bridges NRB1 and NRB2 may overlap the first well region W1 vertically (e.g., in the Z direction). The first and second N-type active bridges NRB1 and NRB2 may not overlap the second well region W2 vertically (e.g., in the Z direction). According to example embodiments, the first and second N-type active bridges NRB1 and NRB2 may each be apart from the second well region W2 horizontally (e.g., in the X direction).

The first and second P-type active bridges PRB1 and PRB2 may overlap the second well region W2 in the vertical (e.g., Z) direction. The first and second P-type active bridges PRB1 and PRB2 may not overlap the first well region W1 vertically (e.g., in the Z direction). In example embodiments, the first and second P-type active bridges PRB1 and PRB2 may each be apart from the first well region W1 horizontally (e.g., in the X direction).

The device isolation layer 16 may be between the first and second PMOS regions PRX1 and PRX2. The first PMOS region PRX1 may be apart from the second PMOS region PRX2 horizontally (e.g., the X direction) with the device isolation layer 16 therebetween.

Referring to FIGS. 2, 3A and 3B, contacts for respectively forming the first and second nodes N1 and N2 may not be between the first and third switching electrodes 21 and 22 and between second and fourth switching electrodes 22 and 24. Accordingly, in the integrated circuit 1, a gate pitch CPP that is a distance in the Y direction between the first and third switching electrodes 21 and 23 and between the second and fourth switching electrodes 22 and 24 may be decreased, and the integration density of the integrated circuit 1 may be increased. According to example embodiments, the gate pitch CPP may be in a range between about 50 nanometers (nm) and about 150 nm. Furthermore, a distance between switching electrodes in a cell adjacent to the integrated circuit 1 and the first through fourth switching electrodes 21 through 24 of the integrated circuit 1 may be increased, and thus, a production yield of a semiconductor device may be improved.

Referring to FIGS. 2 and 3C, the third and fourth switching electrodes 23 and 24 may each extend across the channel regions 13 in the X direction. The third and fourth switching electrodes 23 and 24 may each further include a portion overlying the device isolation layer 16. According to example embodiments, the third and fourth switching electrodes 23 and 24 may be disposed on the channel regions 13 of the active layer 12 and the device isolation layer 16. The third and fourth switching electrodes 23 and 24 may be spaced apart from each other in the X direction.

The third switching electrode 23 may include a switching electrode (e.g., a gate electrode) of the first pull-up transistor PU1 and a switching electrode (e.g., a gate electrode) of the first pull-down transistors PD1. The fourth switching electrode 24 may be a switching electrode (e.g., a gate electrode) of the second pass transistor PG2. Alternatively or additionally, in a manner similar to the first and second switching electrodes 21 and 22, the first and second switching electrodes (e.g., first and second switching electrodes 21 and 22 of FIG. 3A), a gate dielectric layer, a gate conductive layer, gate spacers, and a gate silicide layer may be further provided near the third and fourth switching electrodes 23 and 24.

The device isolation layer 16 may be between the second PMOS and NMOS regions PRX2 and NRX2. The second PMOS region PRX2 may be apart from the second NMOS region NRX2 in the horizontal (e.g., X) direction with the device isolation layer 16 therebetween.

The first interlayer insulating layer 31 may cover the third and fourth switching electrodes 23 and 24. The second interlayer insulating layer 32 may cover side surfaces of the second tie-down contact 43 and the second switching contact 44.

The second tie-down contact 43 and the second switching contact 44 may each extend in a direction (e.g., the Z direction) perpendicular to the substrate 10. The second switching contact 44 and the second tie down contact 43 may each include, but are not limited to, conductive materials, such as Al and Cu. Alternatively or additionally, passivation layers including TiN (not shown) may be further provided between the first and second interlayer insulating layers 31 and 32 and the second switching contact 44 and between the first and second interlayer insulating layers 31 and 32 and second first tie-down contact 43.

The second switching contact 44 may be configured to be electrically connected to the fourth switching electrode 24. The second switching contact 44 may be in contact with the fourth switching electrode 24. The second switching contact 44 may be a second word line contact WLC2 for connecting the word line (e.g., WL of FIG. 1) to the fourth switching electrode 24.

According to example embodiments, the first tie-down contact 42 may have a bar shape extending in the horizontal direction (e.g., the Y direction). According to example embodiments, the second tie-down contact 43 may extend in a direction (e.g., the Y direction) perpendicular to the direction (e.g., the X direction) in which the third switching electrode 22 extends.

In example embodiments, the second tie-down contact 43 may be configured to be electrically connected (e.g., coupled) to the second electrode PU2E2 of the second pull-up transistor PU2 and the second switching electrode 22. In example embodiments, the second tie-down contact 42 may contact each of the second electrode PU2E2 of the second pull-up transistor PU2 and the third switching electrode 23. In example embodiments, the second electrode PU2E2 of the second pull-up transistor PU2 and the third switching electrode 23 may be short-circuited to each other by the second tie-down contact 43. According to example embodiments, the second tie-down contact 42 may be the second node N2 of FIG. 1. According to example embodiments, a gate electrode of the first pull-up transistor PU1 and a gate electrode of the first pull-down transistor PD1 may be connected to the second electrode PU2E2 of the second pull-up transistor PU2 via the second tie-down contact 42.

Referring to FIGS. 2 and 3D, a first round corner R1 may be located between the first electrode PG1E1 of the first pass transistor PG1 and the first active bridge AB1, a second round corner R2 may be located between the second electrode PD1E2 of the first pull-down transistor PD1 and the first active bridge AB1, and third and fourth round corners R3 and R4 may be arranged between the second electrode PU1E2 of the first pull-up transistor PU1 and the first active bridge AB1.

In a lithography process and an etching process for forming the integrated circuit 1, the first NMOS region NRX1, the first through fourth round corners R1 through R4 may be provided due to a local layout effect among the first NMOS region NRX1, the first active bridge AB1, and the first PMOS region PRX1. According to example embodiments, due to the formation of the first round corner R1, an effective area of the first electrode PG1E1 of the first pass transistor PG1 may be increased, and accordingly, operating characteristics of the integrated circuit 1 may be improved.

Alternatively or additionally, the first through fourth round corners R1 through R4 may be arranged between the first electrode PG2E1 of the second pass transistor PG2 and the second active bridge AB2, between the second electrode PD2E2 of the second pull-down transistor PD2 and the second active bridge AB2, and between the second electrode PU2E2 of the second pull-up transistor PU2 and the second active bridge AB2.

Referring to FIG. 3E, the first NMOS region NRX1, the first active bridge AB1, and the first PMOS region PRX1 may constitute a first active pattern RP1, and the first active pattern RP1 may have a planar shape overall that is approximately similar to a capital letter H.

According to example embodiments, the second NMOS region NRX2, the second active bridge AB2, and the second PMOS region PRX2 may constitute a second active pattern RP2, and the second active pattern RP2 may approximately have a planar H shape.

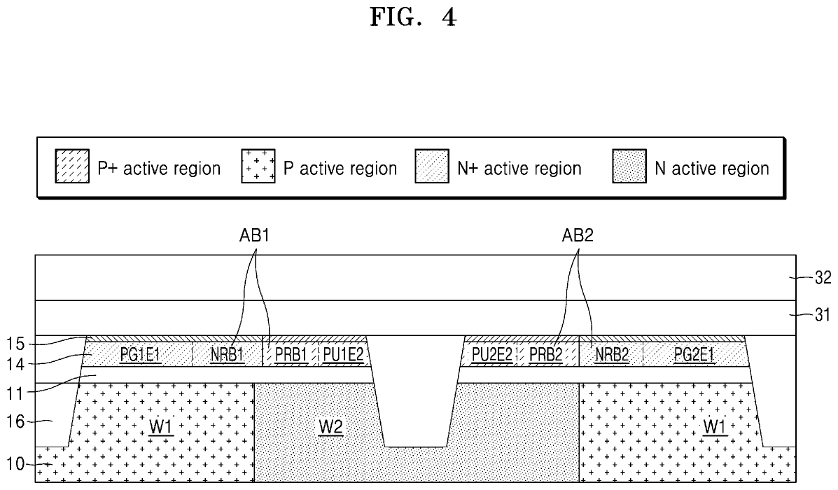

FIG. 4 is a cross-sectional view for explaining an integrated circuit according to other example embodiments and shows a portion corresponding to FIG. 3B.

For convenience of description, descriptions already provided above with respect to FIGS. 2 through 3C will be omitted herein, and differences will be mainly described.

Referring to FIG. 4, one of the first and second N-type active bridges NRB1 and NRB2 may overlap the second well region W2 as well as the first well region W1 vertically (e.g., in the Z direction). For example, the first N-type active bridge NRB1 may overlap the second well region W2 vertically (e.g., in the Z direction). For example, the first P-type active bridge PRB1 may be spaced apart from the first well region W1 horizontally (e.g., in the X direction). Unlike in FIG. 4, the first and second N-type active bridges NRB1 and NRB2 may respectively overlap the first and second well regions W1 and W2 vertically (e.g., in the Z direction).

In example embodiments, the first N-type active bridge NRB1 may have a length in the X direction that is different from that of the second N-type active bridge NRB2. For example, the first N-type active bridge NRB1 may have a length in the X direction that is greater than that of the second N-type active bridge NRB2.

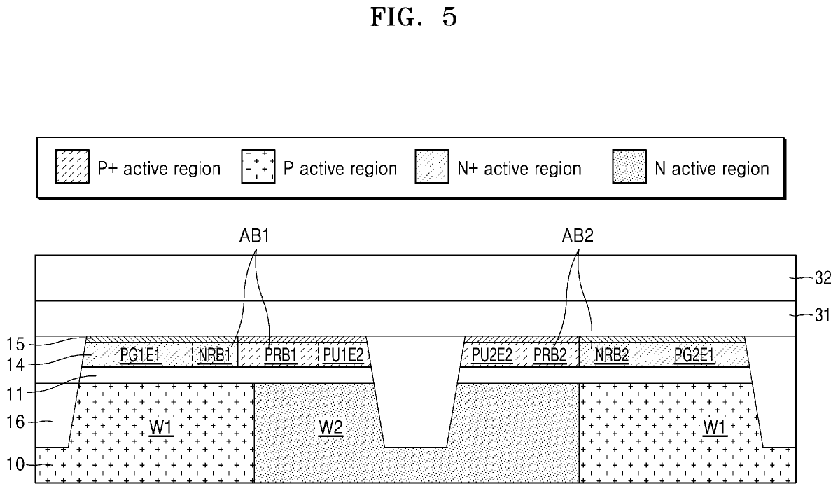

FIG. 5 is a cross-sectional view for explaining an integrated circuit according to other example embodiments and shows the portion corresponding to FIG. 3B.

For convenience of description, descriptions already provided above with respect to FIGS. 2 through 3C will be omitted herein, and differences will be mainly described.

Referring to FIG. 5, one of the first and second P-type active bridges PRB1 and PRB2 may overlap the first well region W1 as well as the second well region W2 vertically (e.g., in the Z direction). For example, the first P-type active bridge PRB1 may overlap the second well region W2 vertically (e.g., in the Z direction). For example, the first N-type active bridge NRB1 may be spaced apart from the second well region W2 horizontally (e.g., in the X direction). Unlike in FIG. 5, the first and second P-type active bridges PRB1 and PRB2 may respectively overlap the first and second well regions W1 and W2 vertically (e.g., in the Z direction).

In example embodiments, the first P-type active bridge PRB1 may have a length in the X direction that is different from that of the second P-type active bridge PRB2. For example, according to example embodiments, the first P-type active bridge PRB1 may have a length in the X direction that is greater than that of the second P-type active bridge PRB2.

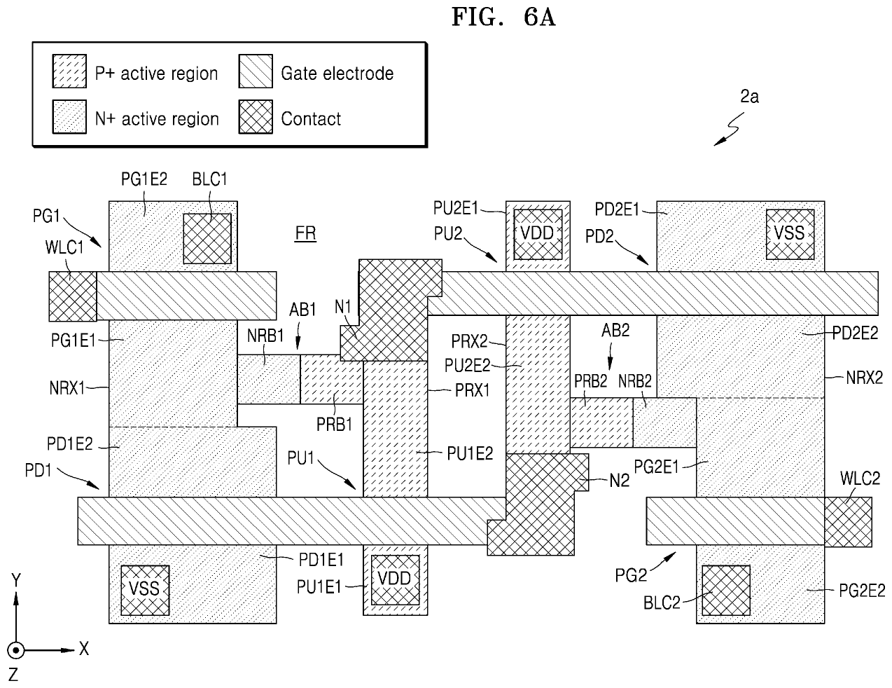

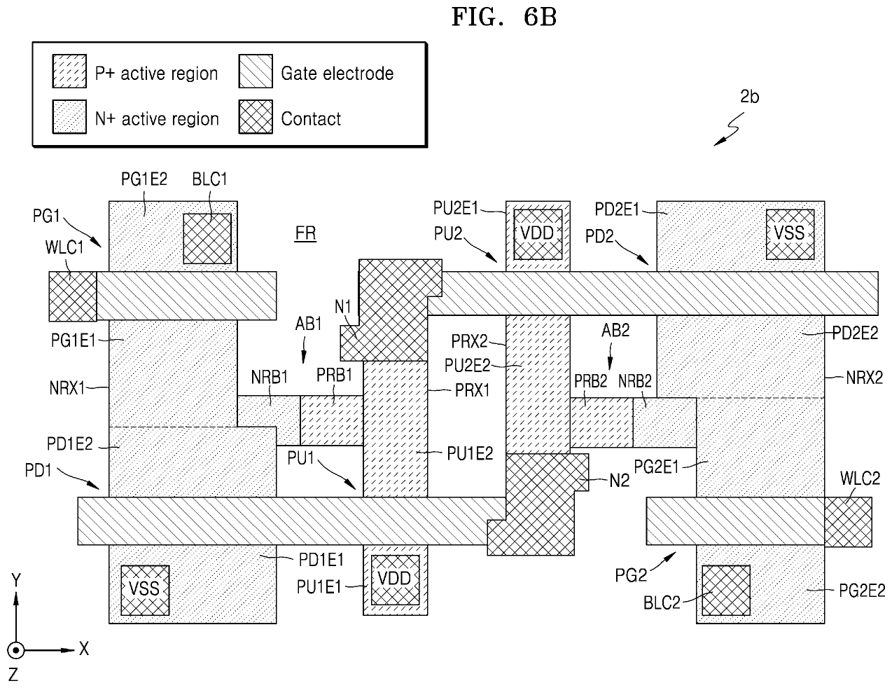

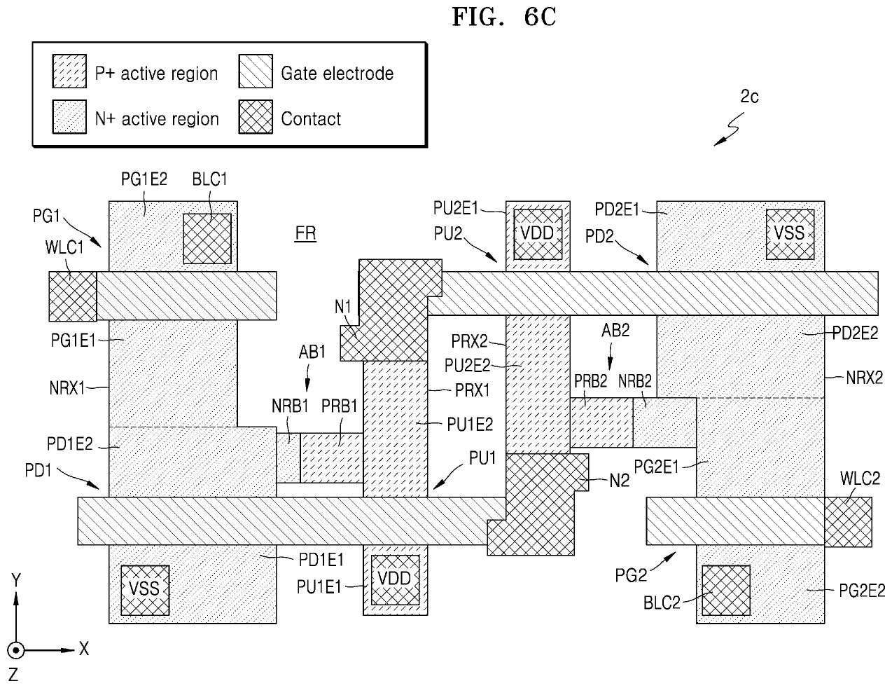

FIG. 6A illustrates a layout of an integrated circuit 2a according to other example embodiments.

For convenience of description, descriptions already provided above with respect to FIGS. 2 through 3C will be omitted herein, and differences will be mainly described.

Referring to FIG. 6A, the first active bridge AB1 of the integrated circuit 2a may be connected to the first electrode PG1E1 of the first pass transistor PG1. In example embodiments, the first active bridge AB1 may be spaced apart from the second electrode PD1E2 of the first pull-down transistor PD1. In example embodiments, the second electrode PD1E2 of the first pull-down transistor PD1 may be connected to a second electrode PU1E2 of the first pull-up transistor PU1 via the first electrode PG1E1 of the first pass transistor PG1 and the first active bridge AB1. For example, the first and second round corners (e.g., R1 and R2 of FIG. 3D) may be each between the first electrode PG1E1 of the first pass transistor PG1 and the first active bridge AB1.

FIG. 6B illustrates a layout of an integrated circuit 2b according to other example embodiments.

For convenience of description, descriptions already provided above with respect to FIGS. 2 through 3C will be omitted herein, and differences will be mainly described.

Referring to FIG. 6B, the first active bridge AB1 of the integrated circuit 2b may be connected to the first electrode PG1E1 of the first pass transistor PG1 and a second electrode PD1E2 of the first pull-down transistor PD1. According to example embodiments, a first side of the first active bridge AB1 parallel to the X direction may overlap the first electrode PG1E1 of the first pass transistor PG1 in the X direction, while a second side of the first active bridge AB1 parallel to the X direction may overlap the second electrode PD1E2 of the first pull-down transistor PD1 in the X direction. According to example embodiments, a boundary between the first electrode PG1E1 of the first pass transistor PG1 and the second electrode PD1E2 of the first pull-down transistor PD1 (e.g., a boundary where a width of the first NMOS region NRX1 in the X direction increases) may overlap the first active bridge AB1 in the X direction.

FIG. 6C illustrates a layout of an integrated circuit 2c according to other example embodiments.

For convenience of description, descriptions already provided above with respect to FIGS. 2 through 3C will be omitted herein, and differences will be mainly described.

Referring to FIG. 6C, the first active bridge AB1 of the integrated circuit 2c may be connected to the second electrode PD1E2 of the first pull-down transistor PD1. In example embodiments, the first active bridge AB1 may be spaced apart from the first electrode PG1E1 of the first pass transistor PG1. In example embodiments, the first electrode PG1E1 of the first pass transistor PG1 may be connected to a second electrode PU1E2 of a first pull-up transistor PU1 via the second electrode PD1E2 of the first pull-down transistor PD1 and the first active bridge AB1. For example, the first and second round corners (e.g., R1 and R2 of FIG. 3D) may be each between the second electrode PD1E2 of the first pull-down transistor PD1 and the first active bridge AB1.

According to example embodiments, as described with reference to FIGS. 6A through 6C, because the first active bridge AB1 on the active layer (e.g., active layer 12 of FIG. 3A) is insulated from the first tie-down contact (e.g., first tie-down contact 42 of FIG. 3A), the first active bridge AB1 may be placed at any suitable position regardless of arrangement of the first tie-down contact 42. Accordingly, high degrees of freedom in design may be provided in manufacturing the integrated circuits 2a through 2c.

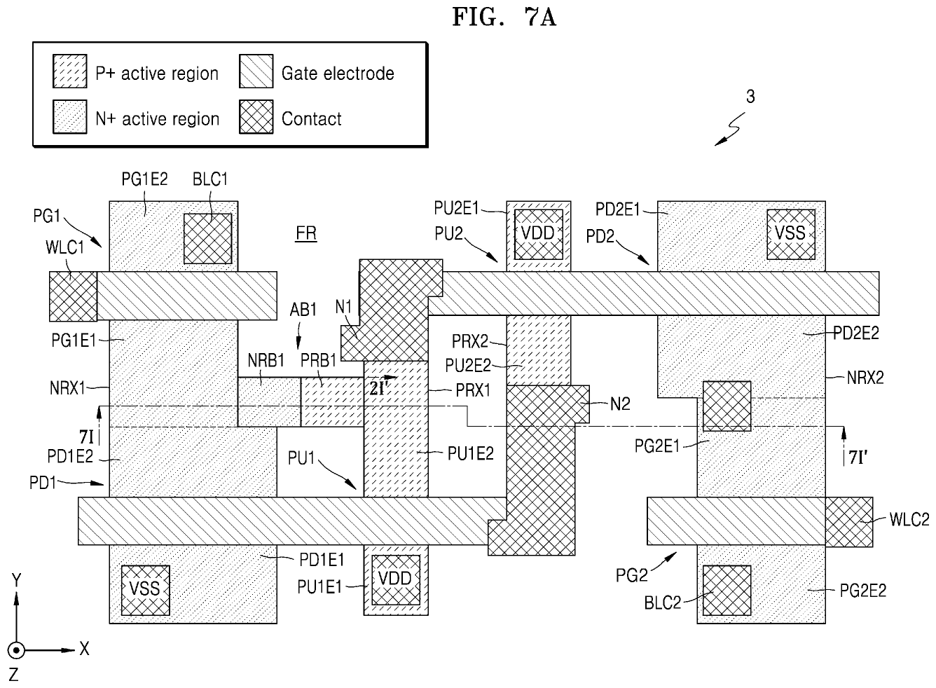

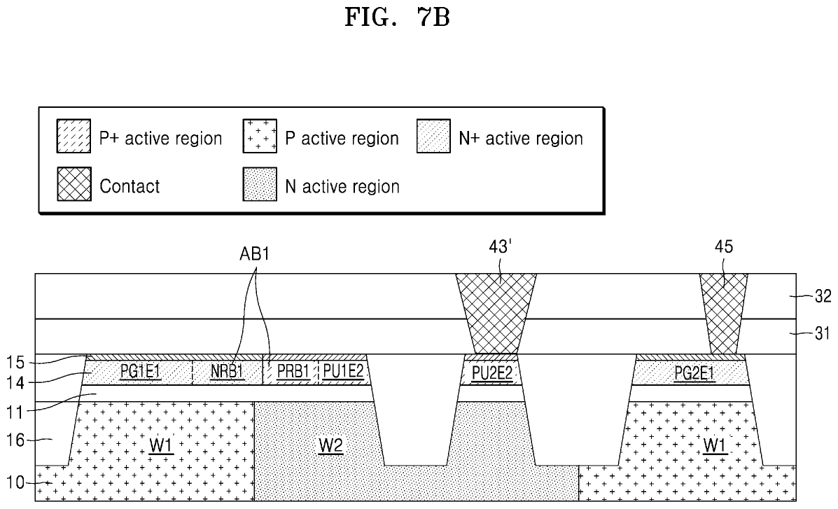

FIG. 7A illustrates a layout of an integrated circuit 3 according to other example embodiments.

FIG. 7B is a cross-sectional view taken along a line 7I-7I′ of FIG. 7A.

For convenience of description, descriptions already provided above with respect to FIGS. 2 through 3C will be omitted herein, and differences will be mainly described.

Referring to FIGS. 7A and 7B, unlike the integrated circuit 1 of FIG. 2, the integrated circuit 3 may not include the second active bridge (e.g., second active bridge AB2 of FIG. 2). The integrated circuit 3 may include only the first active bridge AB1 for connecting the first NMOS region NRX1 to the first PMOS region PRX1. According to example embodiments, the integrated circuit 3 may further include a tie down contact 43′ and a contact 45.

In example embodiments, the tie-down contact 43′ may be connected to the third switching electrode 23 of the first pull-down transistor PD1 and the second electrode PU2E2 of the second pull-up transistor PU2. The tie-down contact 43′ may have a bar shape extending along the Y direction. The tie-down contact 43′ may include a portion overlapping the first electrode PG2E1 of the second pass transistor PG2 in the X direction and a portion overlapping the second electrode PD2E2 of the second pull-down transistor PD2 in the X direction.

According to example embodiments, the contact 45 may overlap each of the first electrode PG2E1 of the second pass transistor PG2 and the second electrode PD2E2 of the second pull-down transistor PD2 in the vertical Z direction. According to example embodiments, the integrated circuit 3 may include a conductive pattern of a first interconnect layer disposed on and connected to the tie-down contact 43′ and the contact 45. Accordingly, the second electrode PU2E2 of the second pull-up transistor PU2 may be connected to the first electrode PG2E1 of the second pass transistor PG2 and the second electrode PD2E2 of the second pull-down transistor PD2 via the tie-down contact 43′, the conductive pattern of the first interconnect layer, and the contact 45.

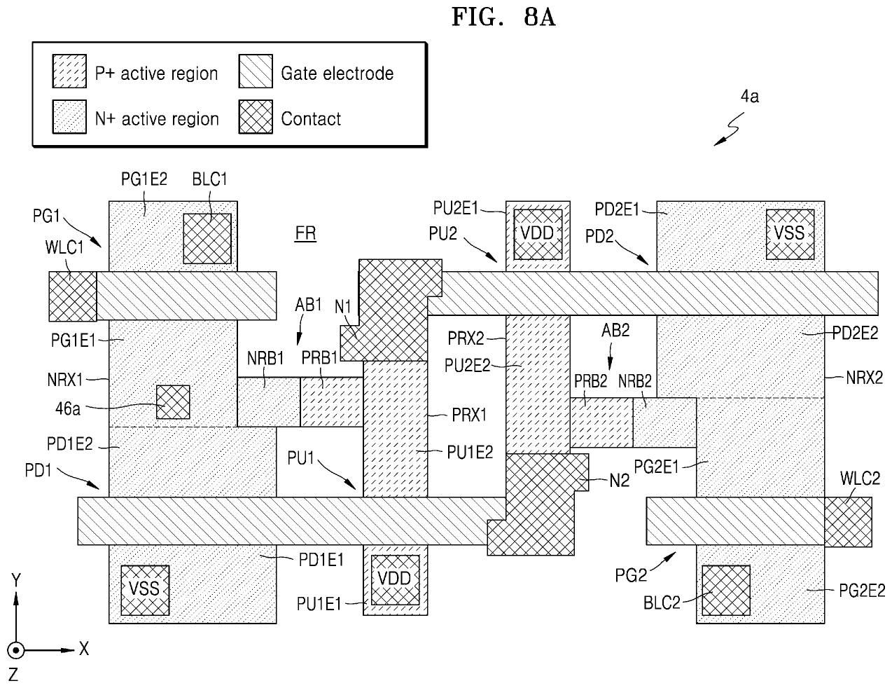

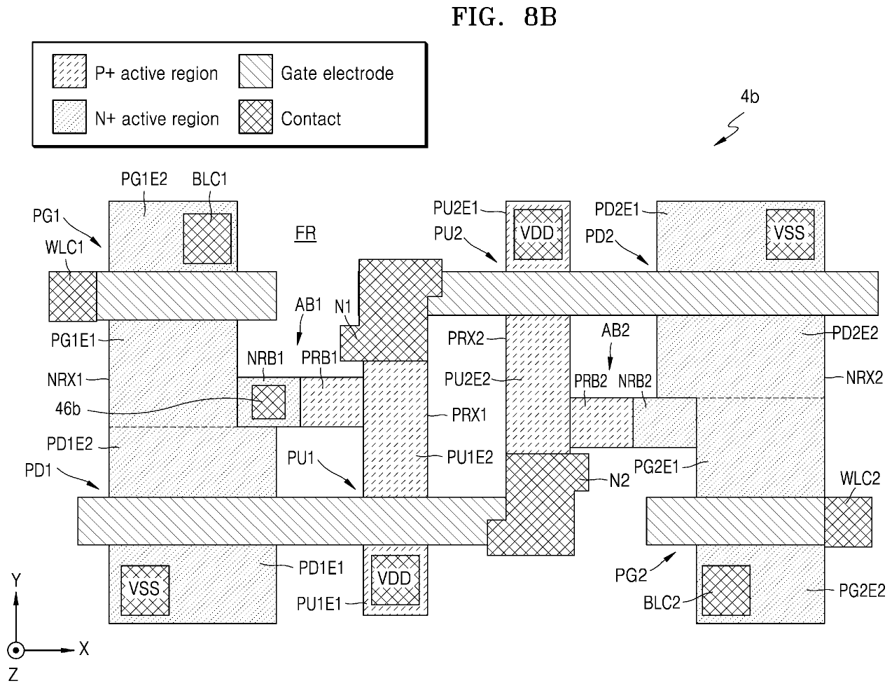

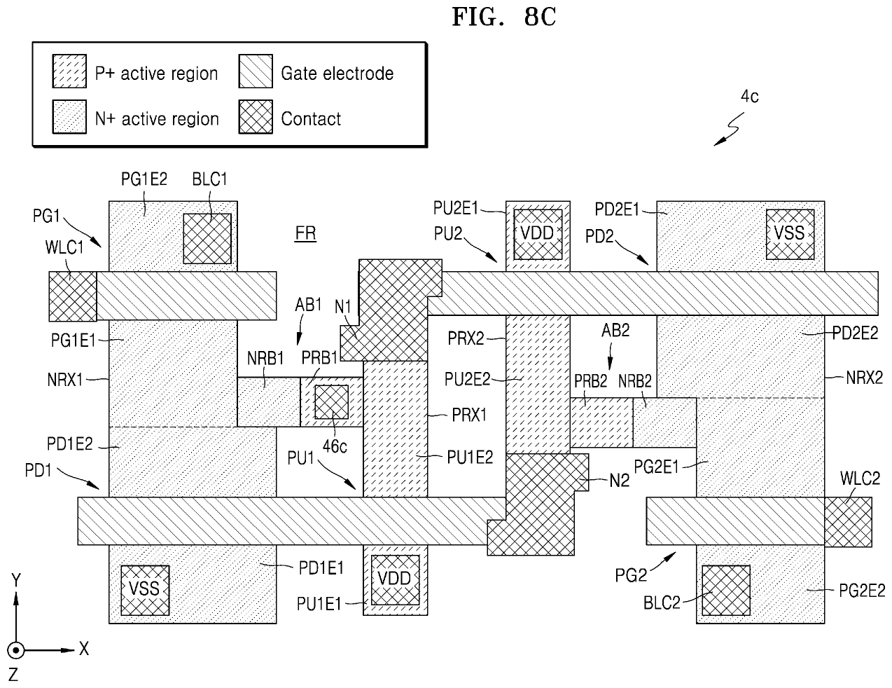

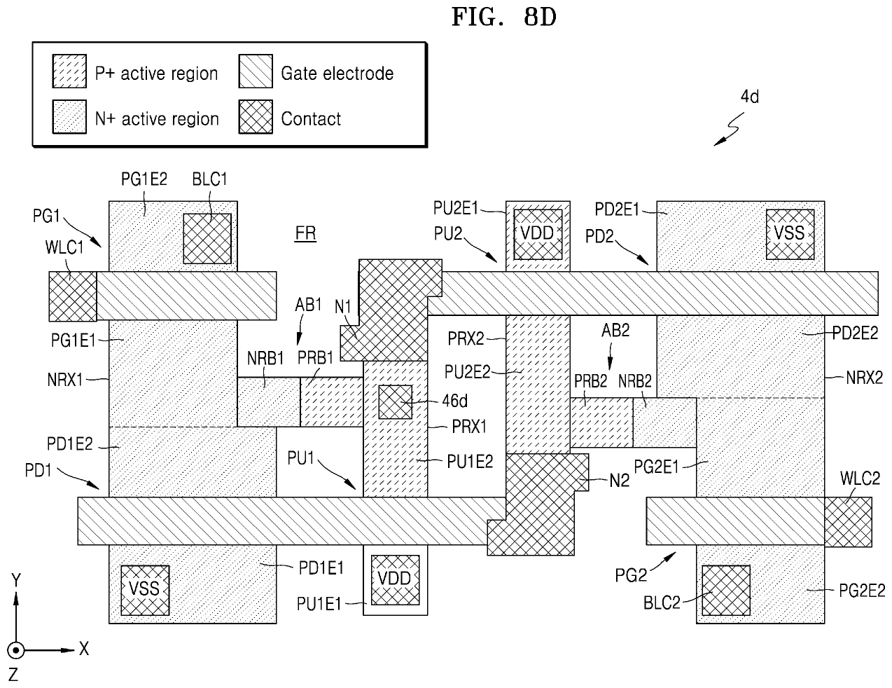

FIG. 8A illustrates a layout of an integrated circuit 4a according to other example embodiments.

For convenience of description, descriptions already provided above with respect to FIGS. 2 through 3C will be omitted herein, and differences will be mainly described.

Referring to FIG. 8A, the integrated circuit 4a is substantially similar to the integrated circuit 1 of FIG. 2, but may further include a contact 46a vertically overlapping the first electrode PG1E1 of the first pass transistor PG1. In example embodiments, the contact 46a may be connected to the first electrode PG1E1 of the first pass transistor PG1. For example, the contact 46a may be at the same level as the first switching contact 41 and the first tie-down contact 42 of FIG. 3A. In example embodiments, a conductive pattern of a first interconnect layer may not be disposed on the contact 46a. Accordingly, an entire top surface of the contact 46a may be in contact with a third interlayer insulating layer (not shown) overlying the first and second interlayer insulating layers (e.g., first and second interlayer insulating layers 31 and 32 of FIG. 3A). In optional or additional embodiments, at least a portion of top surface of the contact 46a may be in contact with the third interlayer insulating layer overlying the first and second interlayer insulating layers 31 and 32.

FIG. 8B illustrates a layout of an integrated circuit 4b according to other example embodiments.

For convenience of description, descriptions already provided above with respect to FIGS. 2 through 3C will be omitted herein, and differences will be mainly described.

Referring to FIG. 8B, the integrated circuit 4b is substantially similar to the integrated circuit 1 of FIG. 2, but may further include a contact 46b that vertically overlaps the first active bridge AB1. According to example embodiments, the contact 46b may vertically overlap the first N-type active bridge NRB1 of the first active bridge AB1. In example embodiments, the contact 46b may be connected to the first N-type active bridge NRB1. For example, the contact 46b may be at the same level as the first switching contact 41 and the first tie down contact 42 of FIG. 3A. In example embodiments, the conductive pattern of the first interconnect layer may not be disposed on the contact 46b. Accordingly, an entire top surface of the contact 46b may be in contact with a third interlayer insulating layer (not shown) overlying the first and second interlayer insulating layers (e.g., first and second interlayer insulating layers 31 and 32 of FIG. 3A). In optional or additional embodiments, at least a portion of top surface of the contact 46b may be in contact with the third interlayer insulating layer overlying the first and second interlayer insulating layers 31 and 32.

FIG. 8C illustrates a layout of an integrated circuit 4c according to other example embodiments.

For convenience of description, descriptions already provided above with respect to FIGS. 2 through 3C will be omitted herein, and differences will be mainly described.

Referring to FIG. 8C, the integrated circuit 4c is substantially similar to the integrated circuit 1 of FIG. 2, but may further include a contact 46c that vertically overlaps the first active bridge AB1. According to example embodiments, the contact 46c may vertically overlap the first P-type active bridge PRB1 of the first active bridge AB1. According to example embodiments, the contact 46c may be connected to the first P-type active bridge PRB1. For example, the contact 46c may be at the same level as the first switching contact 41 and the first tie down contact 42 of FIG. 3A. In example embodiments, the conductive pattern of the first interconnect layer may not be disposed on the contact 46c. Accordingly, an entire top surface of the contact 46c may be in contact with a third interlayer insulating layer (not shown) overlying the first and second interlayer insulating layers (e.g., first and second interlayer insulating layers 31 and 32 of FIG. 3A). In optional or additional embodiments, at least a portion of top surface of the contact 46c may be in contact with the third interlayer insulating layer overlying the first and second interlayer insulating layers 31 and 32.

FIG. 8D illustrates a layout of an integrated circuit 4d according to other example embodiments.

For convenience of description, descriptions already provided above with respect to FIGS. 2 through 3C will be omitted herein, and differences will be mainly described.

Referring to FIG. 8D, the integrated circuit 4d is substantially similar to the integrated circuit 1 of FIG. 2, but may further include a contact 46d that vertically overlaps the second electrode PU1E2 of the first pull-up transistor PU1. In example embodiments, the contact 46d may be connected to the second electrode PU1E2 of the first pull-up transistor PU1. For example, the contact 46d may be at the same level as the first switching contact 41 and the first tie down contact 42 of FIG. 3A. In example embodiments, the conductive pattern of the first interconnect layer may not be disposed on the contact 46d. Accordingly, an entire top surface of the contact 46d may be in contact with a third interlayer insulating layer (not shown) overlying the first and second interlayer insulating layers (e.g., first and second interlayer insulating layers 31 and 32 of FIG. 3A). In optional or additional embodiments, at least a portion of top surface of the contact 46d may be in contact with the third interlayer insulating layer overlying the first and second interlayer insulating layers 31 and 32.

As described with reference to FIGS. 8A through 8D, when necessary, the contacts 46a through 46d respectively overlapping the first electrode PG1E1 of the first pass transistor PG1, the first N-type active bridge NRB1, the first P-type active bridge PRB1, and the second electrode PU1E2 of the first pull-up transistor PU1 may be provided. According to example embodiments, device failures due to optical proximity effects (OPE) in an exposure process may be prevented by providing the contacts 46a through 46d to adjust a density of patterns respectively included in the integrated circuits 4a through 4d.

While the present disclosure has been particularly shown and described with reference to embodiments thereof, it will be understood that various changes in form and details may be made therein without departing from the spirit and scope of the following claims.

1. An integrated circuit, comprising:
a first n-type metal oxide semiconductor (NMOS) region comprising a first electrode of a first pass transistor, a second electrode of the first pass transistor, a first electrode of a first pull-down transistor, and a second electrode of the first pull-down transistor;
a second NMOS region comprising a first electrode of a second pass transistor, a second electrode of the second pass transistor, a first electrode of a second pull-down transistor, and a second electrode of the second pull-down transistor;
a first p-type MOS (PMOS) region between the first NMOS region and the second NMOS region, and comprising a first electrode of a first pull-up transistor and a second electrode of the first pull-up transistor;
a second PMOS region between the first PMOS region and the second NMOS region, and comprising a first electrode of a second pull-up transistor and a second electrode of the second pull-up transistor; and
a first active bridge extending in a first direction and coupling the first NMOS region to the first PMOS region,
wherein each of the first NMOS region, the second NMOS region, the first PMOS region, and the second PMOS region extends in a second direction perpendicular to the first direction, and
wherein a first level of the first active bridge matches:
a level of the first electrode of the first pass transistor,
a level of the second electrode of the first pass transistor,
a level of the first electrode of the first pull-down transistor,
a level of the second electrode of the first pull-down transistor,
a level of the first electrode of the first pull-up transistor, and
a level of the second electrode of the first pull-up transistor.

2. The integrated circuit of claim 1, wherein the first active bridge is configured to electrically couple the first electrode of the first pass transistor, the second electrode of the first pull-down transistor, and the second electrode of the first pull-up transistor.

3. The integrated circuit of claim 1, further comprising a second active bridge configured to couple the second NMOS region to the second PMOS region,
wherein a second level of the second active bridge matches:
a level of the first electrode of the second pass transistor,
a level of the second electrode of the second pass transistor,
a level of the first electrode of the second pull-down transistor,
a level of the second electrode of the second pull-down transistor,
a level of the first electrode of the second pull-up transistor, and
a level of the second electrode of the second pull-up transistor.

4. The integrated circuit of claim 3, wherein the first active bridge comprises a first p-type active bridge doped with a first p-type dopant and a first n-type active bridge doped with a first n-type dopant, and
the second active bridge comprises a second p-type active bridge doped with a second p-type dopant and a second n-type active bridge doped with a second n-type dopant.

5. The integrated circuit of claim 4, wherein the first n-type active bridge is integrated into the first electrode of the first pass transistor and the second electrode of the first pull-down transistor to form a continuous layer.

6. The integrated circuit of claim 4, wherein a first length of the first p-type active bridge in the first direction is greater than a second length of the second p-type active bridge in the first direction.

7. The integrated circuit of claim 4, wherein a first length of the first n-type active bridge has in the first direction is greater than a second length of the second n-type active bridge in the first direction.

8. The integrated circuit of claim 4, wherein the first n-type active bridge is coupled to the first electrode of the first pass transistor, and
wherein the first n-type active bridge is spaced apart from the second electrode of the first pull-down transistor.

9. The integrated circuit of claim 4, wherein the first n-type active bridge is coupled to the second electrode of the first pull-down transistor, and
wherein the first n-type active bridge is spaced apart from the first electrode of the first pass transistor.

10. The integrated circuit of claim 4, wherein the first p-type active bridge is coupled to the second electrode of the first pull-up transistor.

11. The integrated circuit of claim 1, further comprising a buried oxide layer that is in contact with:
a bottom surface of the first active bridge,
a bottom surface of the first electrode of the first pass transistor,
a bottom surface of the second electrode of the first pass transistor,
a bottom surface of the first electrode of the first pull-down transistor,
a bottom surface of the second electrode of the first pull-down transistor,
a bottom surface of the first electrode of the first pull-up transistor, and
a bottom surface of the second electrode of the first pull-up transistor.

12. The integrated circuit of claim 11, further comprising a first switching electrode extending in the first direction between the first electrode of the first pass transistor and the second electrode of the first pass transistor,
wherein the first active bridge is disposed closer to the buried oxide layer than to the first switching electrode.

13. The integrated circuit of claim 12, further comprising a first interlayer insulating layer covering a top surface of the first switching electrode,
wherein the first interlayer insulating layer is in contact with an entire top surface of the first electrode of the first pass transistor, an entire top surface of the second electrode of the first pass transistor, an entire top surface of the first electrode of the first pull-down transistor, and an entire top surface of the second electrode of the first pull-down transistor.

14. An integrated circuit, comprising:
a substrate comprising a first well region doped with a first p-type dopant and a second well region doped with a first n-type dopant;
a buried oxide layer on the substrate and comprising an insulating material; and
an active layer separated from the substrate by the buried oxide layer, the buried oxide layer being between the substrate and the active layer,
wherein the active layer comprises:
a first electrode of a first pass transistor doped with a second n-type dopant;
a second electrode of the first pass transistor doped with a third n-type dopant;
a first electrode of a first pull-down transistor doped with a fourth n-type dopant;
a second electrode of the first pull-down transistor doped with a fifth n-type dopant;
a first electrode of a first pull-up transistor doped with a second p-type dopant;
a second electrode of the first pull-up transistor doped with a third p-type dopant; and
an active bridge configured to electrically couple the first electrode of the first pass transistor, the second electrode of the first pull-down transistor, and the second electrode of the first pull-up transistor.

15. The integrated circuit of claim 14, wherein the active bridge comprises an n-type active bridge doped with a sixth n-type dopant and a p-type active bridge doped with a fourth p-type dopant.

16. The integrated circuit of claim 15, wherein the n-type active bridge vertically overlaps the first well region, and
the p-type active bridge vertically overlaps the second well region.

17. The integrated circuit of claim 16, wherein the n-type active bridge is horizontally apart from the second well region, and
the p-type active bridge is horizontally apart from the first well region.

18. The integrated circuit of claim 15, wherein the n-type active bridge vertically overlaps the second well region, and
the p-type active bridge is horizontally apart from the first well region.

19. The integrated circuit of claim 15, wherein the p-type active bridge vertically overlaps the first well region, and
the n-type active bridge is horizontally apart from the second well region.

20. A static random access memory (SRAM), comprising:
a first active pattern having a letter H planar shape;
a second active pattern having a letter H planar shape and being spaced apart from the first active pattern in a first direction;
a first switching electrode vertically overlapping the first active pattern, the first switching electrode extending in the first direction on the first active pattern;
a second switching electrode that vertically overlaps the first active pattern and the second active pattern, the second switching electrode being spaced apart from the first switching electrode in the first direction, and extending in the first direction on the first active pattern and the second active pattern;
a third switching electrode that vertically overlaps the first active pattern and the second active pattern, the third switching electrode being spaced apart from the first switching electrode in a second direction perpendicular to the first direction, and extending in the first direction on the first active pattern and the second active pattern; and
a fourth switching electrode that vertically overlaps the second active pattern, the fourth switching electrode being spaced apart from the third switching electrode in the first direction, and extending in the first direction on the second active pattern.

21-27. (canceled)
